(19) United States
(12) Patent Application Publication
(10) Pub. No.: US 2025/0012869 A1
(43) Pub. Date: Jan. 9, 2025

(54) BATTERY ABNORMALITY DIAGNOSIS DEVICE

(71) Applicant: Toyota Jidosha Kabushiki Kaisha, Toyota-shi (JP)

(72) Inventors: Akihiro MORITA, Nisshin-shi (JP); Hirotaka Ito, Nagoya-shi (JP)

(73) Assignee: Toyota Jidosha Kabushiki Kaisha, Toyota-shi (JP)

(21) Appl. No.: 18/886,160

(22) Filed: Sep. 16, 2024

(30) Foreign Application Priority Data
Oct. 24, 2003 (JP) 2023-182508

(51) Int. Cl. G01R 31/392; G01R 31/367; G01R 31/3835; G01R 31/389

(52) U.S. Cl. CPC G01R 31/392; G01R 31/367; G01R 31/3835; G01R 31/389

(57) ABSTRACT

A battery abnormality diagnosis device, comprising: an acquisition unit that acquires multiple current values and multiple voltage values within a predetermined period of a battery; a calculation unit that calculates an internal resistance value of the battery based on a dispersion value of the current values, a variation amount of the charging rate of the battery, and the current values and the voltage values, within the predetermined period; and a diagnosis unit that executes abnormality diagnosis processing based on the internal resistance value, wherein the diagnosis unit executes the abnormality diagnosis processing based on the internal resistance value calculated when the dispersion value is equal to or more than a predetermined value and the variation amount is equal to or less than a first threshold, or when the dispersion value is less than the predetermined value and the variation amount is equal to or less than a second threshold.

### CROSS-REFERENCE TO RELATED APPLICATION

This application claims priority to Japanese Patent Application No. 2023-182508 filed on Oct. 24, 2023, incorporated herein by reference in its entirety.

### BACKGROUND

### 1. Technical Field

The present disclosure relates to a battery abnormality diagnosis device.

### 2. Description of Related Art

There is a technique of diagnosing an abnormality of a battery that transmits and receives electric power to and from a motor that is a travel power source for a vehicle, based on an internal resistance value of the battery. The internal resistance value is calculated based on a plurality of current values and a plurality of voltage values of the battery within a predetermined period. Here, when the variance of the current values is small, the calculation accuracy of the internal resistance value may be lowered, and the accuracy of the abnormality diagnosis may be lowered. Therefore, the variance of the current values is ensured by increasing the amount of power consumed by auxiliary devices of the vehicle that uses the battery as a power source (see Japanese Unexamined Patent Application Publication No. 2013-125016 (JP 2013-125016 A)).

### SUMMARY

When the amount of power consumed by the auxiliary devices increases as discussed above, the charging rate of the battery may be lowered, which may affect the travel of the vehicle. Further, the battery is repeatedly charged and discharged even while current values and voltage values for calculating an internal resistance value are being acquired, and the charging rate of the battery varies. If the variation amount of the charging rate is large, the calculation accuracy of the internal resistance value may be lowered, and the accuracy of the abnormality diagnosis may be lowered.

Therefore, an object of the present disclosure is to provide a battery abnormality diagnosis device that ensures the accuracy of an abnormality diagnosis of a battery while suppressing an effect on travel of a vehicle.

The above object can be achieved by a battery abnormality diagnosis device including: an acquisition unit that acquires a plurality of current values and a plurality of voltage values, within a predetermined period, of a battery that transmits and receives electric power to and from a motor that is a travel power source for a vehicle; a calculation unit that calculates an internal resistance value of the battery based on a variance value of the current values within the predetermined period, a variation amount of a charging rate of the battery within the predetermined period, and the current values and the voltage values within the predetermined period; and a diagnosis unit that executes an abnormality diagnosis process for the battery based on the internal resistance value, in which the diagnosis unit executes the abnormality diagnosis process based on the calculated internal resistance value when the variance value is equal to or more than a predetermined value and the variation amount is equal to or less than a first threshold value, or when the variance value is less than the predetermined value and the variation amount is equal to or less than a second threshold value that is less than the first threshold value.

The calculation unit may calculate the variance value, the variation amount, and the internal resistance value every predetermined period.

The calculation unit may calculate a difference between a maximum value and a minimum value of the charging rate within the predetermined period as the variation amount.

The calculation unit may calculate the variation amount based on an integrated value of the current values within the predetermined period.

According to the present disclosure, it is possible to provide a battery abnormality diagnosis device that ensures the accuracy of an abnormality diagnosis of a battery while suppressing an effect on travel of a vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a vehicle;

FIG. 2 is a IV characteristic diagram showing a relation between a current value and a voltage value of a battery;

FIG. 3A is an explanatory view of the effect of the variance value on the calculation accuracy of the inner resistivity value;

FIG. 3B is an explanatory view of an effect of a variance value on calculation accuracy of an inner resistivity value;

FIG. 4A is an explanatory view of an effect of variation in charge rate on accuracy of calculation of an inner resistivity;

FIG. 4B is an explanatory view of an effect of variation in charge rate on accuracy of calculation of an inner resistivity;

FIG. 5 is a flow chart illustrating anomaly diagnostic control; and

FIG. 6 is an explanatory diagram of calculation of a variance value, a variation amount, and an internal resistance value for each predetermined period.

### DETAILED DESCRIPTION OF EMBODIMENTS

### [Outline of Vehicle Configuration]

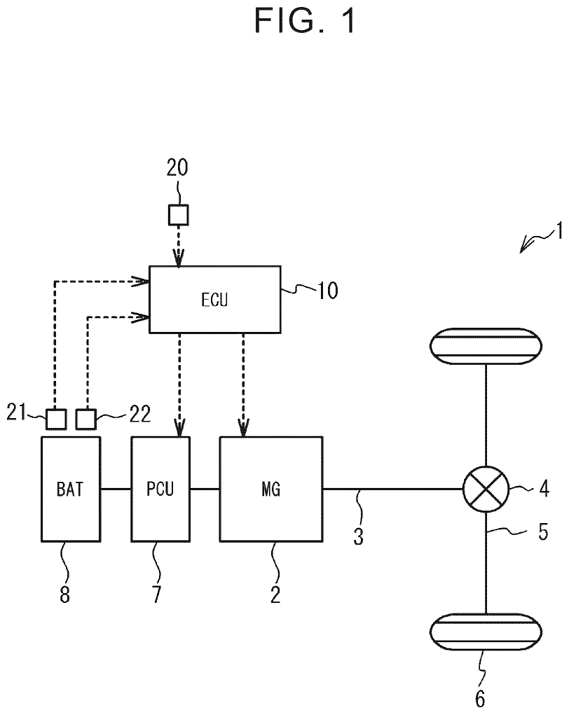

FIG. 1 is a schematic configuration diagram of a vehicle 1. The vehicles 1 are battery electric vehicle equipped with a motor 2 as a driving power source. The vehicle 1 includes a motor 2, a propeller shaft 3, a differential gear 4, a drive shaft 5, drive wheels 6, Power Control Unit (PCU) 7, a battery 8, and an Electric Control Unit (ECU) 10.

The motor 2 functions as an electric motor that outputs torque by power supply. The motor 2 also functions as a generator that generates electric power at the time of braking of the vehicle 1. The electric power stored in the battery 8 is supplied to the motor 2 via PCU 7. The electric power generated by the motor 2 is supplied to the battery 8 via PCU 7. ECU 10 controls PCU 7 to adjust the electric power exchanged between the motor 2 and the battery 8.

The motor 2 is connected to the drive wheels 6 via a propeller shaft 3, a differential gear 4, and a drive shaft 5. When the torque of the motor 2 is transmitted to the drive wheels 6, the vehicle 1 travels.

ECU 10 includes Central Processing Unit (CPU), Random Access Memory (RAM), Read Only Memory (ROM), and a storage device, and performs various kinds of control by executing programs stored in a ROM or a storage device. ECU 10 is an exemplary battery abnormality diagnosis device, and functionally realizes an acquisition unit, a calculation unit, and a diagnosis unit, which will be described in detail later.

The ignition switch 20, the current sensor 21, and the voltage sensor 22 are electrically connected to ECU 10. The ignition switch 20 detects an on-off state of the ignition. The current sensor 21 detects a current of the battery 8. The voltage sensor 22 detects the voltage of the battery 8.

### [Calculation of Internal Resistance Value of Battery 8]

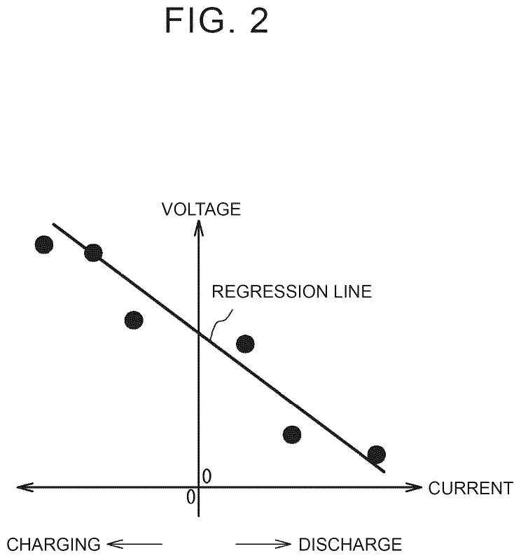

ECU 10 performs anomaly diagnostics of the battery 8 based on the internal-resistance of the battery 8. The internal resistance value of the battery 8 is calculated based on a plurality of current values and a plurality of voltage values of the battery 8. FIG. 2 is a IV characteristic diagram showing the relation between the current value and the voltage value of the battery 8. The horizontal axis represents a current value, and the vertical axis represents a voltage value. ECU 10 acquires the current value and the voltage value of the battery 8 at predetermined time-intervals based on the current sensor 21 and the voltage sensor 22. ECU 10 then plots the current values and the voltage values on IV diagram of FIG. 2. Next, ECU 10 calculates a regression line indicating a relation between a plurality of current values and a plurality of voltage values by regression analysis using the least squares method. ECU 10 calculates the calculated slope of the regression line as the inner resistance of the battery 8.

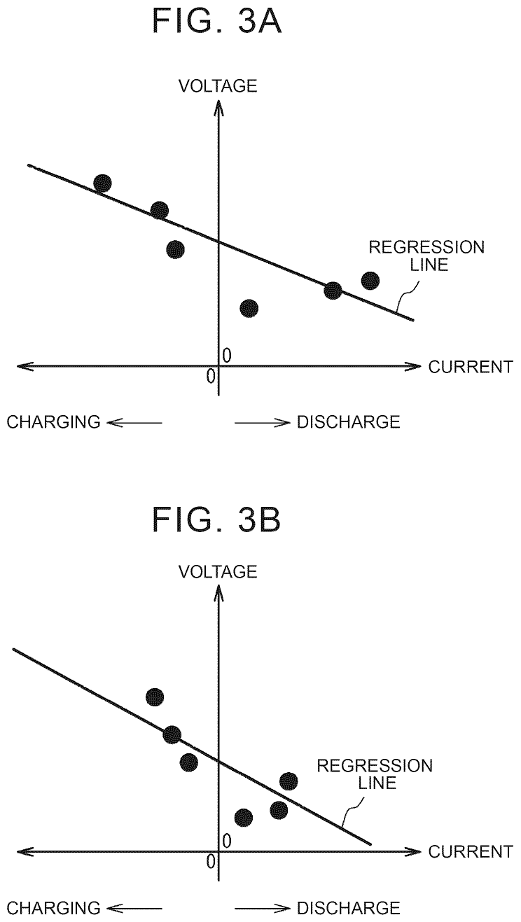

The influence of the dispersion values of the plurality of current values on the calculation accuracy of the internal resistance value will be described. FIGS. 3A and 3B are diagrams for explaining the effect of the variance value on the calculation accuracy of the inner resistivity value. The dispersion value of the current value in FIG. 3A is larger than the dispersion value of the current value in FIG. 3B. In FIG. 3A, a plurality of current values is widely distributed from charge to discharge as compared with FIG. 3B. When the variance value is small as shown in FIG. 3B, for example, when there is a current value largely deviated from another current value, the effect of the current value on the slope of the regression line is large. Therefore, the calculation accuracy of the internal resistance value may be lowered. When the variance value is large as shown in FIG. 3A, even if there is a current value largely deviated from the other current value, the effect of the current value on the slope of the regression line is small. Therefore, the calculation accuracy of the internal resistance value can be ensured. In this way, a larger dispersion value is preferable.

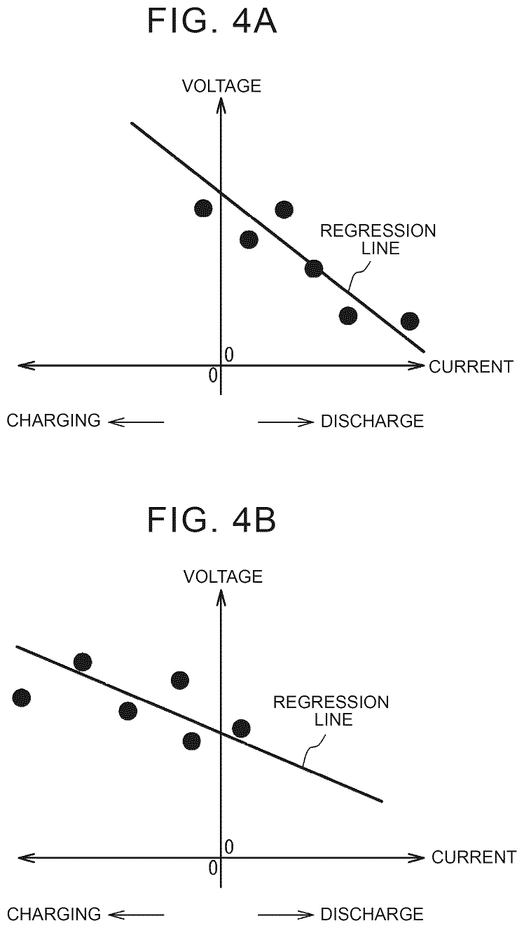

The influence of the variation in the charging rate of the battery 8 on the calculation accuracy of the internal resistance value will be described. FIGS. 4A and 4B are explanatory diagrams for explaining the effect of the variation of the charge rate on the calculation accuracy of the inner resistivity. In FIG. 4A, the plurality of current values is biased toward the discharging side. This indicates that the charge rate is greatly reduced. When the current value is biased toward the discharge side, the influence of the current value on the slope of the regression line is too large, and the calculation accuracy of the internal resistance value may be lowered. In FIG. 4B, the plurality of current values is biased toward the charge side. This indicates that the charge rate is greatly increased. When the current value is biased toward the charging side, the influence of the current value on the slope of the regression line is too small, and the calculation accuracy of the internal resistance value may be lowered. Therefore, it is preferable that the plurality of current values be not biased toward the charging side or the discharging side. In other words, it is preferable that the fluctuation amount of the charge rate is smaller. In the present embodiment, in order to ensure the accuracy of the abnormality diagnosis by securing the calculation accuracy of the internal-resistance value, ECU 10 executes the abnormality diagnosis control by considering the variance value of the current value and the variation amount of the charge rate as follows.

### [Abnormal Diagnostic Control]

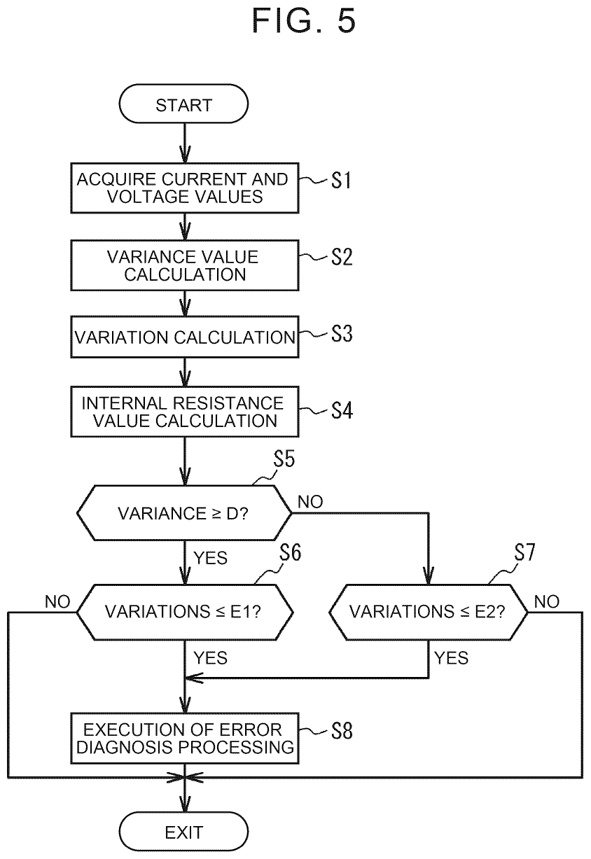

FIG. 5 is a flowchart illustrating abnormality diagnosis control. This control is repeatedly executed during the ignition-on. As described above, ECU 10 acquires a plurality of current values and a plurality of voltage values of the battery 8 within a predetermined time interval (S1). Specifically, ECU 10 acquires a current value and a voltage value at predetermined sampling intervals, and acquires a total of n current values and n voltage values within a predetermined period. S1 is an exemplary process executed by the acquisition unit.

Next, ECU 10 calculates a variance value of the n current values acquired within a predetermined time interval (S2). Specifically, ECU 10 calculates the variance based on the following Expression (1).

$${σ}^{2} = \frac{1}{n} {\sum }_{k = 1}^{n} {( {A}_{k} - μ )}^{2} \qquad ( 1 )$$

σ² is the variance. n is the total number of current values acquired within the predetermined period described above. Aₖ is the k-th obtained current value within a predetermined period. u is an average value of n current values acquired within a predetermined period. S2 is an exemplary process executed by the calculation unit.

Next, ECU 10 calculates the variation of the charge rate of the battery 8 within a predetermined time interval (S3). The variation amount of the charging rate is a difference between the maximum value and the minimum value of the charging rate within a predetermined period. The variation amount of the charging rate within the predetermined period is calculated as follows. A minute variation amount of the charging rate at each sampling interval is calculated based on the current value acquired at each predetermined sampling interval. The minute fluctuation amount is calculated by time integration of the current value. Next, the minute variation amount within a predetermined period is sequentially integrated. The current value used for calculating the minute fluctuation amount is a positive value during charging and a negative value during discharging.

For example, assuming that the capacity of the battery 8 is 1 [Ah], the integrated value of the current value when the battery 8 is charged for 1 second by the current value of 36 [A] is +0.01 [Ah]. In this case, the minute fluctuation amount is +1 [%]. The integrated value of the current value when the battery 8 is discharged for one second according to the current value of 36 [A] is −0.01 [Ah]. In this case, the minute fluctuation amount is −10 [%]. By integrating the minute fluctuation amount calculated sequentially within a predetermined period, the fluctuation amount of the charging rate from the charging rate at the time of starting the predetermined period is calculated as needed.

Based on the variation of the charging rate calculated in this way, the maximum value and the minimum value of the charging rate within a predetermined period are specified. Next, the variation amount is calculated by subtracting the minimum value from the maximum value. S3 is an exemplary process executed by the calculation unit.

Next, ECU 10 calculates the internal-resistance value of the battery 8 based on the n current values and the n voltage values as described above (S4). S4 is an exemplary process executed by the calculation unit.

Next, ECU 10 determines whether or not the variance value is equal to or greater than a predetermined value D (S5). If S5 is Yes, ECU 10 determines whether the variation is less than or equal to the first threshold E1 (S6). If S6 is No, this control ends. If S6 is Yes, ECU 10 performs an anomaly diagnosing process of the battery 8 based on the calculated S8. In the abnormality diagnosis process, when the internal resistance value is within the normal range, the battery 8 is diagnosed as normal, and when the internal resistance value is outside the normal range, the battery 8 is diagnosed as abnormal.

If S5 is No, ECU 10 determines whether the variation is less than or equal to the second threshold E2 (S7). The second threshold E2 is smaller than the first threshold E1. If S7 is No, this control ends. If S7 is Yes, ECU 10 performs an anomaly diagnosing process of the battery 8 based on the calculated S8. S8 is an exemplary process executed by the diagnosis unit.

When the variance value is less than the predetermined value D, the anomaly diagnosing process is executed on the condition that the variation is less than or equal to the second threshold E2 smaller than the first threshold E1. A decrease in the calculation accuracy of the inner resistivity value due to the lower variance value can be suppressed by setting the variation to be equal to or less than the second threshold E2. This ensures accuracy of the abnormality diagnosis. Further, it is not necessary to increase the power consumption of the auxiliary machine in order to secure the variance value. Therefore, it is possible to suppress a decrease in the charging rate of the battery 8 and suppress an influence on the traveling of the vehicle 1, for example, a decrease in the traveling distance.

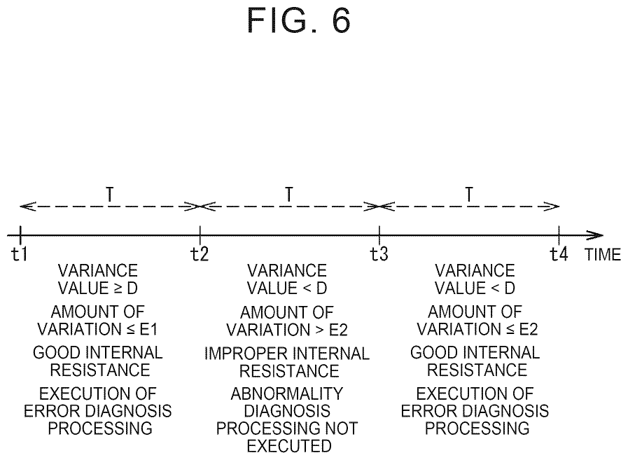

FIG. 6 is an explanatory diagram of calculation of a variance value, a variation amount, and an internal resistance value for each predetermined period. For example, each of the period up to time t1 to t2, the period up to time t2 to t3, and the period up to time t3 to t4 corresponds to the predetermined period T described above. When the variance value in the period up to the time t1 to t2 is equal to or greater than the predetermined value D and the variation amount is equal to or less than the first threshold E1, it is assumed that the calculation accuracy of the internal resistance value in this period is good, and the anomaly diagnostic process is executed based on the internal resistance value. When the variance value in the period up to the time t2 to t3 is less than the predetermined value D and the variation amount is larger than the second threshold E2, it is assumed that the calculation accuracy of the internal resistance value in this period is poor, and the anomaly diagnostic process based on this internal resistance value is not executed. When the variance value in the period up to the time t3 to t4 is less than the predetermined value D and the variation amount is equal to or less than the second threshold E2, it is assumed that the calculation accuracy of the internal resistance value in this period is good, and the anomaly diagnostic process is executed based on the internal resistance value.

In this way, the variance value, the variation amount, and the internal resistance value are calculated for each predetermined period. In addition, the internal resistance value calculated based on the plurality of current values and the plurality of voltage values obtained when the variance value and the variation amount satisfy the above-described condition is used for the abnormality diagnosis process. For example, as compared with the case where the internal resistance value is calculated only when the variance value and the variation amount satisfy the above-described conditions by calculating only the variance value and the variation amount, the complication of the control is avoided.

In the above embodiment, the vehicles 1 that are electrified vehicle have been described as an example, but the present disclosure is not limited thereto. For example, vehicles may be hybrid electric vehicle equipped with engines and motors as driving power sources. In hybrid electric vehicle as well, it is possible to suppress a decrease in the charge rate of the battery caused by an increase in the electric power consumed by the auxiliary machine, thereby suppressing an effect on the traveling of the vehicles, for example, deterioration in fuel consumption.

Although the embodiments of the present disclosure have been described in detail above, the present disclosure is not limited to such specific embodiments, and various modifications and changes can be made within the scope of the gist of the present disclosure described in the claims.

What is claimed is:

1. A battery abnormality diagnosis device comprising:
an acquisition unit that acquires a plurality of current values and a plurality of voltage values, within a predetermined period, of a battery that transmits and receives electric power to and from a motor that is a travel power source for a vehicle;
a calculation unit that calculates an internal resistance value of the battery based on a variance value of the current values within the predetermined period, a variation amount of a charging rate of the battery within the predetermined period, and the current values and the voltage values within the predetermined period; and
a diagnosis unit that executes an abnormality diagnosis process for the battery based on the internal resistance value, wherein the diagnosis unit executes the abnormality diagnosis process based on the calculated internal resistance value when the variance value is equal to or more than a predetermined value and the variation amount is equal to or less than a first threshold value, or when the variance value is less than the predetermined value and the variation amount is equal to or less than a second threshold value that is less than the first threshold value.

2. The battery abnormality diagnosis device according to claim 1, wherein the calculation unit calculates the variance value, the variation amount, and the internal resistance value every predetermined period.

3. The battery abnormality diagnosis device according to claim 1, wherein the calculation unit calculates a difference between a maximum value and a minimum value of the charging rate within the predetermined period as the variation amount.

4. The battery abnormality diagnosis device according to claim 1, wherein the calculation unit calculates the variation amount based on an integrated value of the current values within the predetermined period.
